(19) United States
(12) Patent Application Publication
(10) Pub. No.: US 2018/0309013 A1
(43) Pub. Date: Oct. 25, 2018

(54) SINGLE-CELL ENCAPSULATION AND FLEXIBLE-FORMAT MODULE ARCHITECTURE FOR PHOTOVOLTAIC POWER GENERATION AND METHOD FOR CONSTRUCTING THE SAME

(71) Applicant: Tessolar Inc., Cambridge, MA (US)

(72) Inventors: Jacob Van Reenen Pretorius, Somerville, MA (US); Marco Ferrara, Boston, MA (US)

(21) Appl. No.: 15/963,077

(22) Filed: Apr. 25, 2018

Related U.S. Application Data
(62) Division of application No. 13/922,688, filed on Jun. 20, 2013, now abandoned.
Application No. 13/922,688 is a continuation-in-part of application No. PCT/US11/66135, filed on Dec. 20, 2011.
(60) Provisional application No. 61/424,776, filed on Dec. 20, 2010.

(51) Int. Cl. H01L 31/18; H01L 31/048; H01L 31/044; H01L 31/054; H01L 31/05; H01L 31/02

(52) U.S. Cl. CPC H01L 31/18; H01L 31/048; H01L 31/044; H01L 31/0543; Y02E 10/52; H01L 31/0508; H01L 31/02021

(57) ABSTRACT

A method for encapsulating photovoltaic cells into single functional units is described. These units share the mechanical and electric properties of the encapsulation layers and allow for flexible module architecture to be implemented at the cell level. This enables cost reduction and improved performance of photovoltaic power generation.

### RELATED APPLICATIONS

This application is a divisional of co-pending U.S. application Ser. No. 13/922,688, filed Jun. 20, 2013, entitled SINGLE CELL ENCAPSULATION AND FLEXIBLE-FORMAT MODULE ARCHITECTURE FOR PHOTOVOLTAIC POWER GENERATION AND METHOD FOR CONSTRUCTING THE SAME, which application is a bypass continuation-in-part of co-pending PCT Application Serial No. PCT/US11/66135, filed Dec. 20, 2011, entitled SINGLE CELL ENCAPSULATION AND FLEXIBLE-FORMAT MODULE ARCHITECTURE FOR PHOTOVOLTAIC POWER GENERATION AND METHOD FOR CONSTRUCTING THE SAME, which claims the benefit of copending U.S. Provisional Application Ser. No. 61/424,776, filed Dec. 20, 2010, entitled SINGLE CELL ENCAPSULATION AND FLEXIBLE-FORMAT MODULE ARCHITECTURE FOR PHOTOVOLTAIC POWER GENERATION AND METHOD FOR CONSTRUCTING THE SAME, the entire disclosure of each which applications is herein incorporated by reference.

### FIELD OF THE INVENTION

This invention relates to photovoltaic cell and module manufacturing techniques that increase the robustness, throughput, performance and flexibility of cells and modules to overall reduce the cost of producing electricity from solar panels.

### BACKGROUND OF THE INVENTION

As mankind continues to develop around the world, the demand for energy rises. Most energy used to power machines and generate electricity is derived from fossil fuels, such as coal, natural gas or oil. These supplies are limited and their combustion causes atmospheric pollution and the production of Carbon Dioxide, which is suspected to accelerate the greenhouse effect and lead to global climate change. Some alternative approaches to produce energy include the harnessing of nuclear energy, wind, moving water (hydropower), geothermal energy or solar energy. Each of these alternative approaches has drawbacks. Nuclear power requires large capital investments and safety and waste disposal are concerns. Wind power is effective, but wind turbines require a windy site, often far away from grid connections and take up large footprints of land. Hydropower requires the construction of large, potentially environmentally harmful dams and the displacement of large volumes of flowing water. Geothermal power requires a source of energy that is relatively near the surface—a characteristic not common to a large portion of the Earth—and has the potential to disrupt the balance of forces that exist inside the Earth's crust. Solar is one of the cleanest and most available forms of renewable energy and it can be harnessed by direct conversion into electricity (solar photovoltaic) or by heating a working fluid (solar thermal).

Solar photovoltaic (PV) technology relies on the direct conversion of solar power into electricity through the photoelectric effect: solar radiation's quantized particles, or photons, impinging on semiconductor junctions may excite pairs of conduction electrons and valence holes. These charged particles travel through the junction and may be collected at electrically conductive electrodes to form an electric current in an external circuit.

Photovoltaic is one of the most promising technologies for producing electricity from renewable resources, for a number of reasons: 1. The photovoltaic effect in Si and other solid-state semiconductors is well understood and the technology fully validated; 2. PV power plants convert directly solar power into electrical power, have no moving parts and require low maintenance; 3. Solar radiation is quite predictable and is maximum during hours of peak electricity consumptions; and 4. The industry has been aggressively pursuing a performance improvement and cost reduction path similar to the Moore's law in semiconductor electronics, approaching the condition of market competitiveness with traditional energy resources in many parts of the world. In 2011, approximately 22 GW of solar photovoltaic will be installed globally, over a 40% growth from global installations in 2010 and 180% from 2009.

However, a number of significant issues remain to be solved for photovoltaic to become a mainstream source of electricity in unsubsidized market conditions: 1. PV is still more expensive than traditional energy resources in most parts of the world: while economy of scale and low cost manufacturing will contribute to further reduce cost, technological innovation is needed to achieve market competitiveness more rapidly and on an economically sound and sustainable basis; 2. Manufacturing throughput is still largely inadequate for the potential market need; and 3. Mainstream PV performs poorly in a number of real-world conditions, such as low-light, diffused light, partial shading, temperature excursions, etc.

Therefore, a technology would be desirable which can decrease the cost of photovoltaic energy, increase the throughput and flexibility of PV module manufacturing and resolve a number of the performance issues, while being compatible with the industry value chain. It is also desirable to provide technology, devices and techniques that provide a durable and long-lasting PV.

### SUMMARY OF THE INVENTION

This invention overcomes disadvantage of prior art by providing a system and method that alleviates, for example, the breakage of PV cells in manufacturing lines; the lack of flexibility in module's format and characteristics; and the performance limitations of current PV module architectures in the form of a photovoltaic (PV) device that is constructed using Single Cell Encapsulation (SCE), according to various embodiments. Illustratively, by encapsulating individual PV cells of various dimensions in a multilayer structure comprising a bottom layer, a layer of encapsulant, the PV cell, another layer of encapsulant and the top layer, many benefits including flexible architecture, automated manufacturing, low cell breakage, cell and structure decoupling, etc can be realized.

The bottom layer can consist of various materials (e.g. metals, plastic, glass, etc.), which are chosen in order to optimize mechanical, electrical and thermal transfer properties.

The top layer can consist of various transparent materials (e.g. glass, plastic, teflon, etc.), which are chosen in order to optimize optical mechanical, electrical and thermal transfer properties.

Electric contacts on the front and back of the cell can be already present on the cell or may be applied during single cell encapsulation. In each alternative, the contacts are illustratively extended to reach outside of the sealed structure and can be connected to an external connector.

According to an illustrative embodiment, individual cells are plugged into (operatively connected to) a Flexible-format Module Architecture (FMA). FMA consists of a supporting frame that can be made from various materials formed with associated manufacturing process and dimensions. The FMA can incorporate slots for the insertion of the cells, electrical connections among the cells, power conditioning electronics and mounting solutions. Illustratively, the FMA can allow cells to be replaced when worn or non-functional, or otherwise electrically bypassed without compromising the function of the remaining cells in the FMA.

### BRIEF DESCRIPTION OF THE DRAWINGS

The invention description below refers to the accompanying drawings, of which:

FIG. 1 is an exploded perspective view showing layers comprising an individually encapsulated photovoltaic cell and a complete cell assembly;

FIGS. 2A-2D. are perspective views showing a plurality of possible implementations of SCE bottom layer according to various embodiments;

FIGS. 3A-3C are perspective views showing a plurality of possible implementations of SCE bottom electrode according to various embodiments;

FIGS. 4A-4D are perspective views showing a plurality of possible implementations of SCE top layer according to various embodiments;

FIGS. 5A-5D are perspective views showing a plurality of possible arrangements of SCE top electrode according to various embodiments;

FIGS. 6A-6C show side cross-sections of SCE top layer according various embodiments;

FIG. 7 is an exposed perspective view of a complete cell with electric connector according to an illustrative embodiment;

FIG. 8 is a side cross section of an interconnection method between adjacent SCEs according to an illustrative embodiment;

FIG. 9 is a perspective view showing the insertion of an individually encapsulated cell in the Flexible-format Module Architecture (FMA) according to the illustrative embodiment;

FIGS. 10A and 10B are plan views, respectively, showing a generalized series connection of the cells in the FMA and bypass diodes at the cell level;

FIGS. 11A and 11B are plan views, respectively, showing an implementation of a generalized parallel connection of the cells in the FMA and power-conditioning electronics at the cell level;

FIGS. 12A and 12B are plan views, respectively, showing an illustrative implementation of a hybrid series-parallel connection of the cells in the FMA and power conditioning electronics at each sub-group in parallel;

FIG. 13 is a flow diagram showing one illustrative method to manufacture SCE where solar cells are already connected with the SCE top and bottom electrodes; and

FIG. 14 is a flow diagram showing one illustrative method to manufacture SCE where the interconnection of the solar cell and the SCE top and bottom electrodes is formed during encapsulation.

### DETAILED DESCRIPTION

Single cell encapsulation (SCE) technology according to the illustrative embodiments described below can be a plug-in solution for existing cell and/or module manufacturing lines, which enables the production of lower-cost and higher-performance PV modules, while incorporating a number of desirable features.

Standard cell manufacturing lines produce photovoltaic cells, which consist of a thin (typically ˜200-1 μm) silicon wafer with front and back electrodes. The cells are very fragile and need to be handled with extreme care, and therefore breakage of the cells poses limits on the minimum practical thickness of the cell. On the other hand, thinner cells require less Silicon material and therefore enable lower material cost.

During manufacturing of an integrated solar module, cells are soldered in strings and laid out in a multilayer structure comprising: a bottom layer, such as TPE (Tedlar, Polyster, Ethyl Vinyl Acetate (EVA)), TPT (Tedlar, Polyster, Tedlar), glass, etc.; a layer of encapsulant, such as ethylene vinyl acetate (EVA), polyvinyl butyral (PVB), silicone, polyolefin resins, polydimethylsiloxane (PDMS), polyepoxide resins, etc.; the PV cells; a second layer of encapsulant; and a transparent top layer of glass, which also provides structural integrity. The multilayer structure is then laminated in machines, which combine the layers by pressing them together for approximately 1 to 30 minutes. The lamination time depends on the type of encapsulant and on the encapsulation process, which may or may not include application heat, force and/or vacuum. Finally, an aluminum (or other metal, polymer, composite, etc.) frame is typically adhered to the multilayer structure and the electric box with bypass diodes is connected to the electric contacts from the strings, on the back of the module. The whole process can take up to 1 hour per module with manual assembly. Module line automation is a desirable option for manufacturers in countries with high cost of labor, however automated production lines are quite complex and expensive.

In its generalized implementation, SCE technology includes laminating individual cells in standalone elements with mechanical, thermal and electronic properties. There are numerous advantages to this approach over current techniques as described in prior art, including for example:

1) The bottom layer material can be chosen to optimize thermal transfer.
2) The top layer (glass or other transparent material) can be constructed without regard to structural properties and can be substantially thinner, allowing for higher light transmittance and lower cost.
3) Breakage from handling the cells can practically be eliminated.
4) The encapsulation of each individual cell enables a continuous process, as opposed to batch encapsulation of PV cell assemblies in current PV module lamination methods, which enables a high degree of process control, leading to:

a. Fewer broken cells during encapsulation.

b. High process uniformity.

c. Lower amounts of encapsulant required per cell.

d. Outgoing quality control after single cell encapsulation that enables the accurate measurement of actual cell performance in the field. As a consequence, modules built with SCEs can achieve tight output power distribution at their nominal power rating.

5) According to one embodiment, SCE top and bottom electrodes are laminated onto the solar cell top and bottom electrodes and held in place by either mechanical compression or conductive glue. Soldering to the cells is therefore eliminated, resulting in the following substantial advantages:

a. Solar cell front and back bus bar width can be substantially reduced by 40% to 100%, while maintaining low interconnection resistance, therefore saving on silver paste cost.

b. Screen-printing of the bus bars can become unnecessary: A step is removed from the cell manufacturing line where significant breakage occurs.

c. Soldering onto the cell can cause the formation of micro-cracks, which in turn propagate during the lifetime of the cell, can create macro cracks and substantially degrade the solar cell performance over time.

d. Soldering of solar cells can take up to one man-hour per module when manually executed: a solder-less process enables labor cost savings and achieves greater accuracy and reliability.

Note, as used herein the term “standalone” or “stand-alone” in the context of the illustrative embodiments od SCEs refers to the fact SCEs are each essentially discrete, stand-alone, weatherized components and that the frame used to hold such SCEs is only (illustratively) a supporting structure with interconnections and other features. This arrangement is novel distinct from various prior art implementations, which integrate the frame as a portion of the overall system in terms of weatherization and/or other functions.

These are only some of the immediate advantages in accordance with the teachings herein; SCE is an enabling technology in a number of ways over the current architectures described in prior art:

1) The PV module becomes a flexible-format module architecture (FMA). In one illustrative embodiment, FMA comprises an uncomplicated electronic board pre-fabricated using relatively inexpensive, weather-resistant materials and embedding electric contacts and other power conditioning electronics. In another illustrative embodiment, FMA consist of a supporting frame of highly variable form-factor were SCE are mechanically secured and electrically interconnected.
2) Cells are connected in dedicated slots, which is straightforward to automate.
3) The module's form-factor can be highly variable:

a. In one illustrative embodiment, a large scale FMA, in excess of 1.6 square meters, can hold a large number of SCEs to form a very large scale PV module, or mega-module. Such device can significantly reduce installation cost in large-scale photovoltaic fields or rooftops. The mega-module would be assembled at the factory and include fast mounting fixtures; it would then be transported on-site by special truck carriages, lifted by cranes and rapidly mounted on poles, trackers or other suitable structures.

b. In another illustrative embodiment, the FMA frame would be constructed of materials to replace or augment building envelope materials and its form-factor would be dictated by architectural considerations for building-integrated photovoltaic (BIPV) or building-applied photovoltaic (BAPV). Examples of such applications are:
i. Photovoltaic curtains of highly variable form-factors.
ii. Photovoltaic roofs of highly variable form-factors.
iii. Photovoltaic rails and trims.
iv. Individual photovoltaic tiles.
   4) It is unnecessary in the implementations of the embodiments herein to connect the PV cells in series, as is common practice in prior implementations: in a generalized configuration, a by-pass diode can be embedded at the cell point of contact to solve the problem of shading at the cell level. More advanced, power-optimizing solutions that even include active control can be implemented at moderate cost increase;
   5) Notably, cell technology innovation and PV plant infrastructure can be decoupled: i.e. in manufacturing cells according to the embodiments herein, the cells in a PV system can be replaced when new cells become available; the old cells can be recycled in low-tier applications where lower efficiencies are tolerated: an independent, dynamic market for cells is therefore created with product differentiation instead of a fairly static and undifferentiated industry (PV panels). Likewise, it is contemplated that cells can be replaced in the filed or that panels can be recycled and upgraded with newer technology without completely disposing of the old panel. Moreover, decoupling is highly desirable to fully leverage the fast cycles of cell technology innovation in renewable energy penetration (cell cycles are 5 years or less versus 20 years of infrastructure constructions);
   6) Individual SCEs can be packaged more tightly for transportation;
   7) Individual SCEs can be handled more conveniently for repair and recycling;
   8) Individual SCEs in a module can be replaced when their performance degrades below a nominal threshold in such a way that modules built with SCEs can maintain high yield over their rated lifetime;
   9) SCE technology can be applied to any types of cells, including, but not limited to:

a. Pure semiconductors, such as Silicon, Germanium, etc.

b. Compound semiconductors, such as Indium Gallium Arsenide (InGaAs),

Indium Gallium Phosphide (InGaP), Gallium Arsenide (GaAs), etc.

c. Thin film semiconductors, such as amorphous Silicon (a-Si), Cadmium

Telluride (CdTe), Copper Indium Gallium Selenide (CuInGaSe), etc.

10) SCE enables hybrid modules incorporating different cell technologies performing better in different environmental conditions.

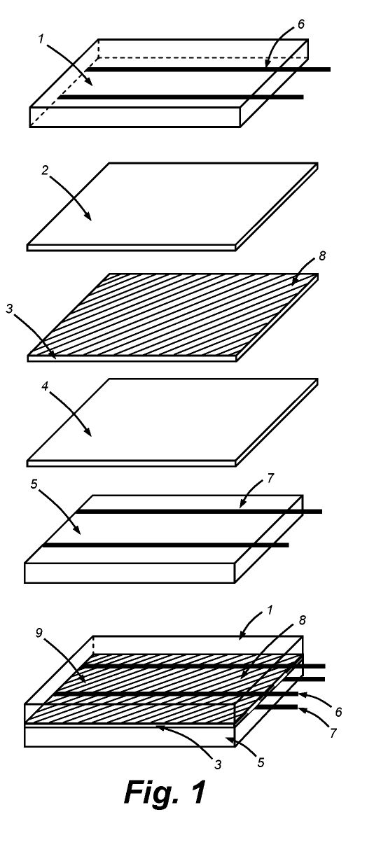

An illustrative embodiment of an integrated encapsulated solar cell (SCE) is shown in FIG. 1. SCE 9 consists of several layers that are combined during a lamination process to encapsulate and protect solar cell 3 within transparent SCE top layer 1 and SCE bottom layer 5.

As will be known to those skilled in the art, solar cell 3 is equipped with front and back electrodes, which are employed to extract the photocurrent generated by the incoming solar radiation. The cell front electrode usually comprises a large number of fingers, approximately 10 to 20 micrometers high and 50 to 200 micrometers wide, and several bus bars, approximately 10 to 20 micrometers high and 1.5 to 3 millimeter wide. The main function of the bus bars is to collect the electric current from all the fingers and to offer a soldering pad for the strips of metal, known as tabs, which interconnect solar cells in a module. Cell top layer 8, on which the cell front electrode is formed, is usually a Silicon Nitride layer added for optical efficiency and electrical passivation. Cell top layer 8 is non-conductive and a manufacturing process is employed to make electric contact to solar cell 3 through cell top layer 8. An example of such a process is where the cell front electrode is screen-printed using a conductive paste, usually containing Silver particles. The cell is then baked at high temperature, which allows some of the paste to diffuse though the Silicon Nitride in order to make electric contact with solar cell 3. The cell back electrode usually comprises an Aluminum-based layer covering the full extent of the back of solar cell 3 and several bus bars, approximately 10 to 20 micrometers high and 3 to 5 millimeter wide. Akin to cell front electrode, the cell back electrode is usually screen-printed and baked at high temperature into solar cell 3. Alternatively, both the cell front electrode and the cell back electrode can reside on the bottom face of solar cell 3. Several methods are available for creating such a configuration, including Metal-Wrap-Through (MWT), Emitter-Wrap-Through (EWT) and Interdigitated-Back-Contact (IBC), as it is known to those skilled in the art. In an embodiment, the cell front and back electrodes are assumed to be an integral part of solar cell 3. However, it is contemplated that such electrodes can also be created during the SCE process described herein.

SCE top electrode 6 is connected with the cell front electrode and SCE bottom electrode 7 is connected with the cell back electrode, therefore guaranteeing electrical access to the cell from outside the SCE package. In one illustrative embodiment, the cell front electrode is located on the top face of solar cell 3; however, it should be clear and apparent to those skilled in the art that the scope of the various embodiments extends to other cell electrode configurations, including, but not limited to, MWT, EWT and IBC configurations, in which cases SCE top electrode 6 is relocated to the back of solar cell 3.

In one illustrative embodiment of a lamination process, SCE 9 consists of a sandwich of multiple layers that, in order, include a transparent SCE top layer 1 such as glass, acrylic, teflon or other transparent materials as known to those skilled in the art. SCE top electrode 6, made from appropriate conducting materials such as copper, aluminum, other conductive metals and conductive non-metals whether they are transparent or non-transparent, is placed between SCE top layer 1 and cell top layer 8 of solar cell 3. SCE top electrode 6 can be integrated into SCE top layer 1 in multiple ways as known to those skilled in the art or can be a standalone layer. Top encapsulant layer 2, consisting of a thermo-set or non-thermo-set materials characterized by low Equilibrium Moisture Content (EMC) of less than 0.2% at 85C and 85% relative humidity and by low surface tension of less than 30 mN/m, such as polydimethylsiloxanes, is placed between SCE top layer 1 and solar cell 3. It is recognized that certain types of encapsulants can be desirabbel for use in the illustrative SCE architecture—for example those that are characterized by (a) very low EMC and (b) very high wetting properties. Illustratively, acceptable thresholds for these two physical parameters (a and b) can be provided. For example, the EMC was found to be 0.28% for EVA and only 0.035% for PDMS at 85C/85% RH in a recent study by Dow Corning (See: http://onlinelibrary.wiley.com/doi/10.1002/pip.1025/abstract). Additionally, silicones have a surface tension of 20.4 mN/m, while that of EVA is in the range 30-36). See: http://www4.dowcorning.com/content/publishedlit/silicones_in_industrial_applications_internet_version_080325.pdf and www.vtcoatings.com/plastics.htm. The bottom encapsulant layer 4, consisting of thermo- or non-thermo-set materials of similar properties as top encapsulant layer 2, is placed between the back of solar cell 3 and SCE bottom layer 5. SCE Bottom layer 5 can be a multitude of materials chosen for a specific additional feature of SCE 9. By way of example, SCE bottom layer 5 provides weather, impact and electrical insulation to solar cell 3. In another embodiment, SCE bottom layer 5 can incorporate additional functions and processes, such as electronics, micro fluidics for cooling and purification, advanced cooling and other chemical, mechanical and electrical functions that are powered by the solar electricity generated by solar cell 3. SCE bottom electrode 7 is placed between SCE bottom layer 5 and the back of solar cell 3. SCE bottom electrode 7 can be integrated into SCE bottom layer 5 in multiple ways as known to those skilled in the art or can be a standalone layer. The lateral dimensions of the SCE can be 100-200 mm. Illustratively, the thickness of the layers can be as follows: SCE top layer 1 1-4 mm for glass, 0.13-1.3 mm for Teflon; top encapsulant layer 2 0.001-1.5 mm; solar cell 3 0.001-0.2 mm; bottom encapsulant layer 4 0.001-1.5 mm and SCE bottom layer 5 0.2-0.5 mm. The aforementioned materials and thickness values are illustrative of a wide range of possible materials and dimensions.

In the example of using thermoset materials as encapsulant, the aforementioned sandwich of multiple layers is then placed under pressure while exposing it to heat in a ubiquitous lamination process. The heat of the process initially softens and allows encapsulant layers 2 and 4 to melt and flow. Pressure applied to the sandwich while encapsulant layers 2 and 4 are melted, squeezes encapsulant material out between SCE top electrode 6 and cell top layer 8, allowing SCE top electrode 6 to make electric contact with the cell front electrode. Similarly flow of bottom encapsulant layer 4 under pressure allows for SCE bottom electrode 7 to make electric contact with the cell back electrode. The temperatures employed in the process are illustratively in the range of 25° C. to 1,000° C.

After sustained exposure to heat, the polymer material of encapsulant layers 2 and 4 will cross link, bonding to all material that is in contact with it. Hence, SCE top layer 1 and cell top layer 8 will be bonded in a similar manner as the back of solar cell 3 and SCE bottom layer 5. However, since all encapsulant has flowed under pressure from between SCE electrodes 6 and 7, a suitable electric connection between the cell electrodes and the SCE electrodes is ensured. Because such interconnection process is solder-less, the bus bars on the front and the back of solar cell 3 can be made free of bus bars. Therefore, the width of such bus bars can be substantially reduced or the bus bars can be entirely omitted from the structure, with significant savings in conductive paste usage. The lamination bond secures solar cell 3 between SCE top layer 1 and SCE bottom layer 5, giving it the mechanical properties of the respective layers and forming SCE 9. This lamination is durable and reduces the risk that the inner layer will crack.

In one possible variation of the lamination process, SCE top electrode 6 can be placed between top encapsulant layer (also termed “encapsulat top layer”) 2 and cell top layer 8. Likewise, SCE bottom electrode 7 can be placed between bottom encapsulant layer (also termed “encapsulant bottom layer”) 4 and the back of solar cell 3.

As yet another alternative, SCE top electrode 6 can be directly attached to the cell front electrode by soldering, ultrasonic welding, conductive glue or other suitable technique, as it will appear to those skilled in the art. Likewise, SCE bottom electrode 7 can be directly attached to the cell back electrode by similar process or technique.

As will be appreciated by those skilled in the art, thermosetting it one of many processes available to bond the sandwiched layers of the SCE 9 according to an embodiment. For example in another variation of the lamination process, a PDMS (silicone) encapsulant can be used. Silicone can be tailored to cure with the addition of heat, ultra-violet light (UV) or a catalyst or a combination of the aforementioned in just a few minutes. Furthermore, silicone can be tailored to have a specific hardness and Young modulus of choice. Commercial silicone encapsulants feature a number of properties that make them ideal for SCE, for example: High transparency; Stability to ultra-violet light; High breakdown voltage; Superior volume resistivity; Excellent adhesion to glass and other SCE relevant materials. By virtue of the low equilibrium moisture content and excellent weather resistance of silicone encapsulants, SCEs can be made with very small clearance between the edge of solar cell 3 and the edge of integrated SCE 9, thereby enabling a high packaging density of PV cells in PV modules. The weatherization of PV cells can be further improved by an additional layer of suitable sealant applied around the edges of SCE 9, which should be clear to those skilled in the art.

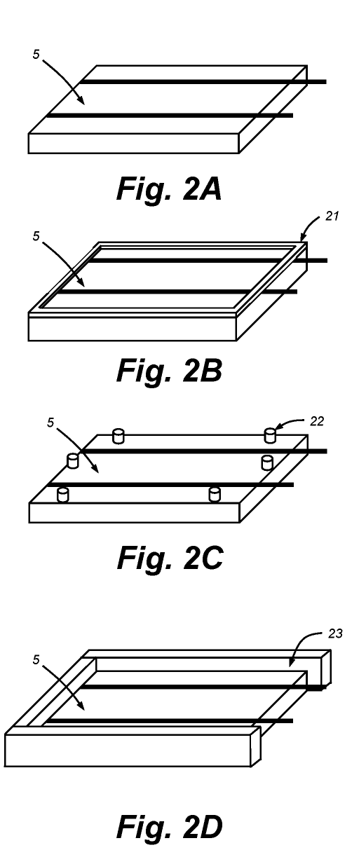

During lamination, it can be desirable to employ a physical structure to prevent layers from slipping and misaligning with respect to each other as bonding layers cure. FIG. 2 illustratively shows possible solutions implemented on SCE bottom layer 5 in order to seat the cell, facilitate the alignment of layers and avoid layer slippage during lamination. An alignment mask 21 in FIG. 2B can be superimposed onto SCE bottom layer 5 before lamination; a number of dimples 22 can either be punched, fixed into or casted into SCE bottom layer 5 as shown in FIG. 2C; or dent 23 can be created in SCE bottom layer 5 by either depressing the center, by attaching borders to the outer sides or by casting it as part of SCE bottom layer 5 (FIG. 2D). Furthermore, the restraining structures can be separate from the sandwich materials, and can be applied externally as will be known to those skilled in the art. These are a few examples and there are a wide variety of techniques to mechanically retain the cell and other layers during lamination that are clear to those skilled in the art.

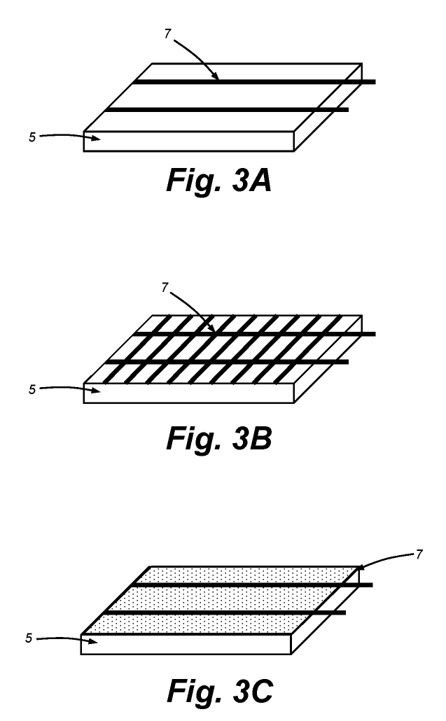

FIG. 3 illustrates SCE bottom electrode 7 superimposed on SCE bottom layer 5 in various illustrative embodiments. SCE bottom electrode 7 can be made from appropriate conducting materials such as copper, aluminum, other conductive metals and conductive non-metals that offers sufficiently low electrical resistance in order to conduct electricity with minimal losses. SCE bottom electrode 7 can be formed in a number of patterns on SCE bottom layer 5 by processes know to those skilled in the art. These include printing, plating, etching, bonding, depositing (by chemical as wells as physical processes and structures) among a wide variety of possible techniques, processes and structures. These processes allow for the electrode to take on a plurality of patterns as shown in FIG. 3. These include in a basic form one or more straight lines (FIG. 3A), a mesh or grid (FIG. 3B) or a full back contact (FIG. 3C). The choice of pattern is dependent on a number of factors such as conductivity, cost, heat transfer properties, quality of contact during lamination to name a few. Overall, SCE bottom electrode 7 has the flexibility to take on a multitude of forms from a number of materials, thereby allowing for functional flexibility that can be designed into the invention.

As an alternative, SCE bottom electrode 7 can consist of several conductive strips of metal independent of SCE bottom layer 5, also known as tabs, of the type conventionally used to interconnect solar cells in PV modules. The tabs can be located either between SCE bottom layer 5 and bottom encapsulant layer 4 or between bottom encapsulant layer 4 and the back of solar cell 3.

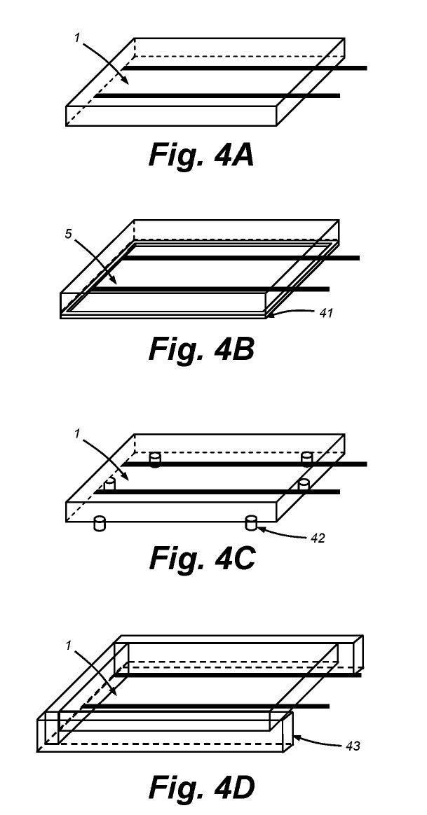

FIG. 4 shows further possible embodiments of a technique that facilitates alignment of the layers and avoids layer slippage during lamination, which are alternative to the embodiments illustrated in FIG. 2. In the present embodiments, the structures are integrated with, or connected to, transparent SCE top layer 1. As shown in FIG. 4B, an alignment mask 41 can be superimposed to SCE top layer 1 before lamination; a number of dimples 42 can either be punched, fixed into or casted as part of SCE top layer 1 as illustrated in FIG. 4C; or a dent 43 in FIG. 4D can be created in SCE top layer 1 by either depressing the center, by attaching borders to the outer sides or by casting it as part of SCE top layer 1. These implementations are illustrative of a variety of possible techniques that can be implemented by those skilled in the art.

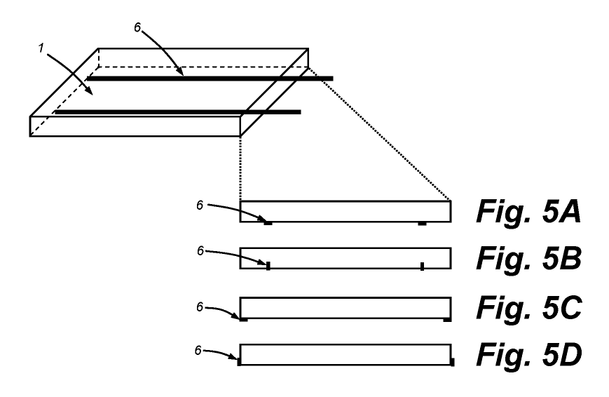

SCE top electrode 6 serve to conduct electricity generated from the solar cell 3. However, when made from non-transparent material, they also reduce the amount of light that penetrates cell top layer 8, thereby effectively reducing the efficiency of solar cell 3. In FIG. 5, SCE top electrode 6 can be integrated as part of SCE top layer 1 though processes such as printing, plating, etching, bonding, depositing (by chemical as well as physical mechanisms and techniques) and a variety of other processes, or can be a standalone layer, many combinations and methods that should be clear to those skilled in the art. These methods allow for flexibility in the electrode design to allow for minimal electric losses though the electrodes while maintaining high solar cell efficiency. FIG. 5 illustrates a plurality of arrangements that take advantage of the flexibility offered by the numerous techniques available to create SCE top electrode 6.

In one embodiment as illustrated in the cross section of FIG. 5A, SCE top electrode 6 is a flat (planar), straight substrate superimposed on transparent SCE top layer 1 (a “flush orientation”). In another embodiment, as shown in the cross section of FIG. 5B, SCE top layer 1 has been created with cavities such that SCE top electrode 6 can be inserted (embedded) into the layer as a vertical substrate and resides relative flush with one side thereof (a “vertical embedded orientation”). These vertical substrates allow for SCE top electrodes 6 with high frontal area and thus low resistance but minimal blocking of light or shadowing of the solar cell, especially when used in combination with a tracker. Another possible embodiment includes configuring electrodes at the corners of SCE top layer 1 as shown in the cross section of FIG. 5C such that SCE top electrode 6 is only casting a shadow on the solar cell during certain parts of the day (an “edge orientation”). In yet another embodiment, SCE top electrode 6 is placed on the side of SCE top layer 1 as shown in the cross section of FIG. 5D (a “side orientation”). SCE top electrode 6 still protrudes from the bottom of SCE top layer 1 so that electric contact will be made with the solar cell during lamination.

As an alternative, SCE top electrode 6 can consist of a plurality of conductive strips of metal independent of SCE top layer 1, also known as tabs, of the type conventionally used to interconnect c-Si cells in PV modules. The tabs can be located either between SCE top layer 1 and top encapsulant layer 2 or between top encapsulant layer 2 and cell top layer 8.

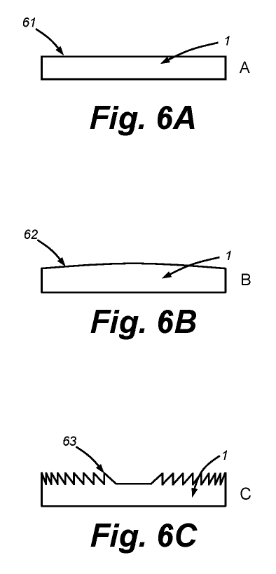

Traditional PV modules incorporate a multiplicity of cells in one final assembly step. A large transparent layer, typically glass (but alternatively a durable, weather-resistant polymer), resides on top of the cells. Traditionally, this transparent layer has been of rectangular cross section. This cross section is an optimization of structural and cost features. Since the transparent layer of SCE is a single piece of material, and is generally free of system-wide structural requirements, it can define a wide variety of shapes to optimize the optical efficiency of the device. In one embodiment as shown in the cross section of FIG. 6A, SCE top layer 1 has a traditional flat (planar) surface 61. However, the material thickness can be substantially reduced since the structural requirements of the SCE are significantly lower than that of an entire module. The cross section of FIG. 6B illustrates another embodiment of SCE top layer 1 that defines a non-planar shape on at least one side thereof. Here surface 62 is convex, allowing for light that enters it to be bent and light paths to be optimized. In yet another embodiment, SCE top layer 1 has a Fresnel (or functionally similar geometry) lens 63 integrated in it as shown in FIG. 6C. The Fresnel lens allows for light to be deflected based on the design of the lens. The aforementioned shapes serve as an illustration of the flexibility in cross sectional shape that SCE allows for SCE top layer 1. The possible benefits of utilizing these or other shapes for optimizing light paths are well known to those skilled in the art. By virtue of the significantly smaller footprint than prior implementations, SCE top layer 1 achieves the same mechanical stability as the front glass of conventional photovoltaic modules, at substantially reduced thickness and constructed free of any tempering or other hardening processes. Reduced thickness and elimination of additional processing steps for the top glass can result in substantial cost savings and possibly improve light transmittance and efficiency.

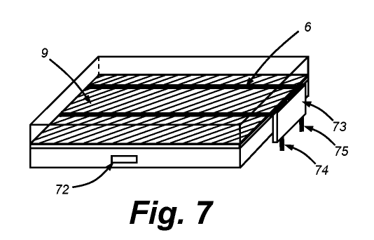

To increase flexibility of the SCE, it can be desirable to incorporate mechanical arrangements for structurally and electrically coupling the SCE to other SCEs in a module. In FIG. 7 an illustrative embodiment of such connections is shown. Electric connector 73 is a weatherized pin connector such as those made by Molex Corporation of Lisle, IL. These connectors allow for electrodes to be mechanically secured, stress relieved, electrically insulated and protected from the environment through an interface that provides standard connections to the outside world. Connector 73 has a positive pin 74 and negative pin 75, connected to SCE top electrode 6 and SCE bottom electrode 7 respectively. The standard electric interface allows for the SCE to be connected to any circuitry also from a third party vendor by just specifying the mating connection. It is further contemplated that arrangements for electrically connecting cell can be provided within the FMA structure and need not be integrated within the SCE. Mechanical slot 72 is an example of how the SCE will be mechanically connected to a supporting structure. In this example, a lock pin slides into slot 72 and secures and anchors SCE to the supporting structure as will be apparent to anyone skilled in the art.

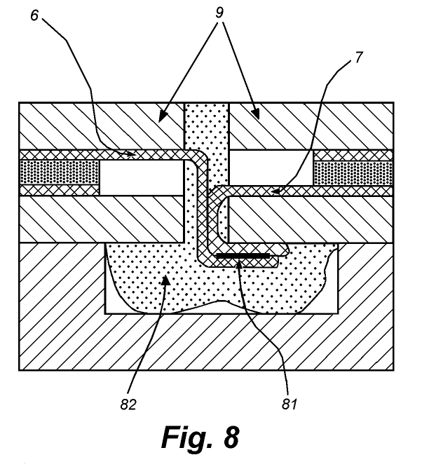

FIG. 8 illustratively shows a side cross section of an embodiment in which the SCE top electrode 6 is directly connected to SCE bottom electrode 7 of an adjacent SCE to form interconnection 81. Interconnection 81 is illustratively weatherized using an electrically insulating material 82, which can consist of silicone gel, shrink wrap or other suitable materials that provide high electric resistance and protect the connection from the elements. A number of methods are available to create reliable interconnections such as soldering, ultrasonic welding, crimping, etc., which are well known to those skilled in the art. The shape of interconnection 81 is just one of a wide variety of layouts, where a path is created in order to comply with mechanical deformations of SCE and FMA components.

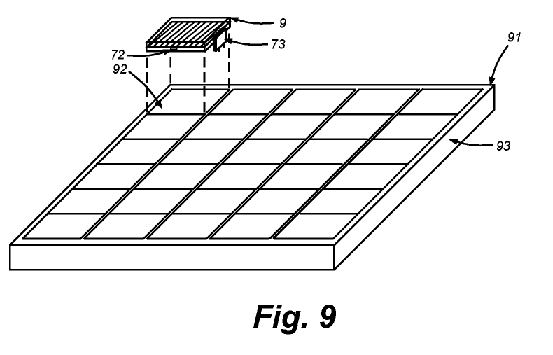

FIG. 9 illustratively shows a Flexible-format Module Architecture (FMA) and how SCEs fit into such architecture by employing the structural and electrical connections described above. FMA 91 can consist of a supporting frame (or substrate) 93, which can be made of various weather-resistant metals, composites, plastics (for example PET, fiber reinforced PPE+PS, etc.), and other materials, with many manufacturing processes of said materials, such as extrusion, cold and hot pressing, injection molding and others, as it will be apparent to those skilled in the art. In another embodiment, FMA 91 can consist of a grid-like structure 93 with cross section optimized to withstand the mechanical load and stresses on the PV module.

In one possible embodiment, FMA 91 incorporates slots 92 for mechanical connection 72 and electrical connection 73 of SCE 9. In another illustrative embodiment, adjacent SCEs are directly connected to one another, as shown and described above in FIG. 8, and subsequently anchored to slots 92 by mechanical connectors, glue or other suitable techniques known to those skilled in the art.

SCEs 9 can be inserted in the FMA 91 by a ubiquitous pick-and-place robot, widely used in the automation industry, and implemented in accordance with ordinary skill. These robots are able to move and insert SCEs 9 rapidly and precisely, without causing breakage due to the mechanical resistance of individually encapsulated cells. Alternatively, SCEs 9 can be directly connected to one another to form strings and strings can be subsequently mounted and interconnected on FMA 91.

FMA 91 can also incorporate electrical interconnections between cells, electrical interconnections between strings of cells and power conditioning electronics, both at the cell level and at the module level. As an illustrative example, electrical by-pass diodes can be co-molded at each SCE in order to isolate individual SCEs in case of partial shading or failure. More generally, the FMA can include electrical connections that interconnect predetermined of the cells together, the electrical connections including bypass diodes constructed and arranged to enable inoperative cells and cells that are functioning poorly (e.g. shaded cells or degraded cells) to be bypassed in an overall electrical connection of the cells. As another illustrative example, the junction box containing string-level electrical by-pass diodes can be incorporated in FMA 91 by co-molding it into the structure. Alternatively, each cell's positive and negative electrode can be wired to the junction box where sophisticated cell level power optimization electronics can regulate the power generated by each cell. These are just some of a wide variety of implementations of FMA-integrated power conditioning electronics according to various non-limiting examples and embodiments.

Furthermore, FMA 91 can include a plurality of mounting solutions (not shown), which allow seamless and low-cost integration of the module in a photovoltaic power plant. Such mounting solutions can be posts, pedestals, holes, screws, interlocking mechanisms, ballasts, and many others, as it will be apparent to those skilled in the art.

One of the advantages of SCE 9 and FMA 91 is the flexibility of electrical configurations attainable for PV cells. Electrical interconnections built into FMA 91 can have a larger cross section and lower resistance than those of conventional PV modules, because they do not fall in the light path and can avoid being routed in the tight spaces between neighboring cells. In one embodiment, electric connections departing from SCE electrodes 6 and 7 of all SCEs 9 in FMA 91 converge into a central electronic board where they are interconnected in series, parallel or hybrid configuration, with or without power conditioning electronics, as it will be clear to those skilled in the art. In an alternate embodiment, each SCE 9 is connected directly to its immediate neighboring cells and the power conditioning electronics is located on or near SCE 9.

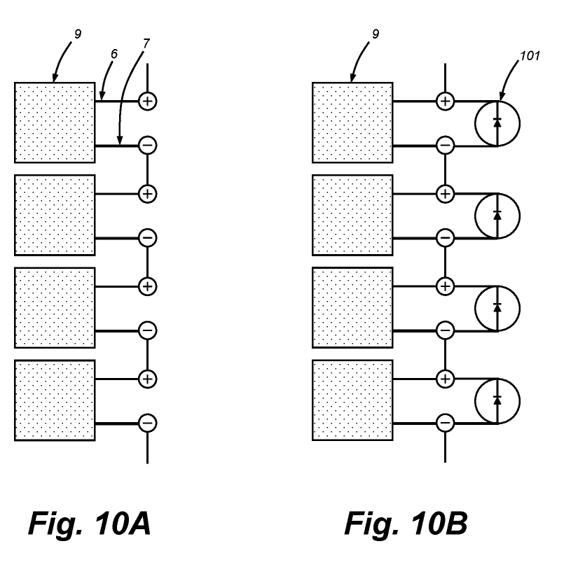

In one embodiment of the circuitry of FMA 91, SCEs 9 are connected in series (FIG. 10) as is common with solar modules based on current implementations: SCE top electrode 6 of each cell is connected to SCE bottom electrode 7 of the neighboring cell either directly or by using a conductor housed inside FMA 91. FIG. 10A shows a basic series configuration, while FIG. 10B shows a series configuration with power conditioning electronics added in parallel to each cell. By way of example, bypass diodes 101 can be added between SCEs 9 to address one of the biggest problems in PV modules: When one cell's performance is degraded by fouling, cracking or other eventualities, it affects the entire system's power output because the cell can dissipate power instead of generating it. The addition of bypass diodes 101 between cells negates the influence of individual cells performance on the module performance and is one possible technique to increase module performance in real-life operating conditions. In certain embodiments of the invention, individual defective SCEs can be disconnected and replaced by new SCEs in order to guarantee high yield of the module for its rated lifetime.

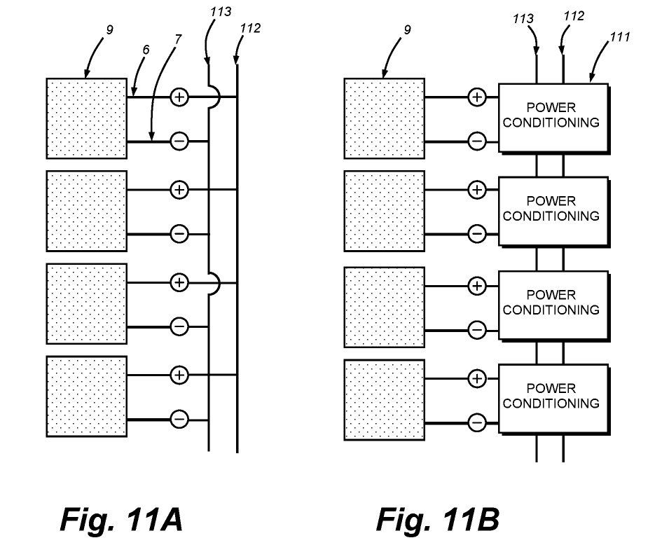

In another embodiment, FMA 91 circuitry connects SCEs 9 in parallel as shown in FIG. 11. SCE top electrodes 6 of all cells are connected to bus bar 112, while SCE bottom electrodes 7 are connected to bus bar 113. FIG. 11A shows a basic parallel configuration, while FIG. 11B shows a parallel configuration with power conditioning electronics 111 at the cell level: power conditioning electronics 111 receives the current and voltage between SCE top electrode 6 and SCE bottom electrode 7 as an input, modifies said current and applies output current and voltage to bus bars 112 and 113. In one embodiment, power conditioning electronics 111 can include one stage of maximum power point tracking, which changes the operating point of SCE 9 to optimize the power output, and one stage of DC-DC power conversion, which steps up the operating voltage, all of which are understood by those skilled in the art. In another embodiment, power conditioning electronics 111 can execute DC-AC conversion at the cell level and output an AC signal to bus bars 112 and 113.

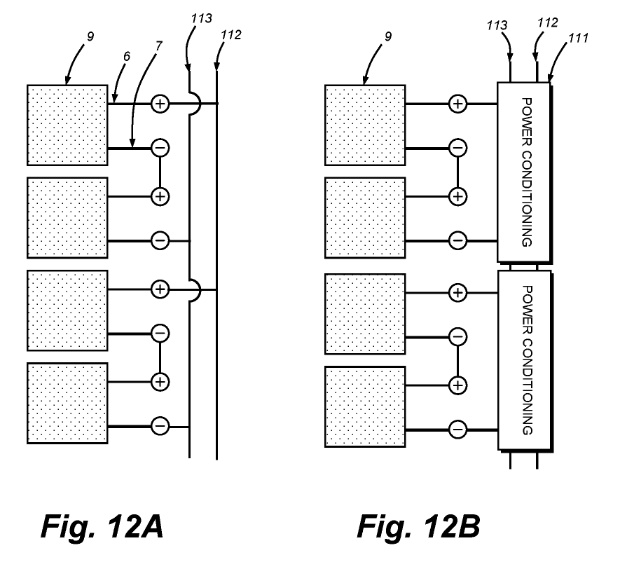

FIG. 12 illustrates another embodiment of application of flexible electronic architecture. Here a hybrid series-parallel connection of SCEs 9 in FMA 91 is illustrated: sub-groups of SCEs 9 are connected in series and the resulting circuits are then connected in parallel. FIG. 12A shows a generalized hybrid configuration, while FIG. 12B shows a hybrid configuration with power conditioning electronics 111 at the sub-group level.

It should be clear that SCE, FMA and methods for constructing the same, according to the illustrative embodiments described herein, provide a flexible-format module architecture to be implemented at the cell level. This enables cost reduction and improved performance of photovoltaic power generation.

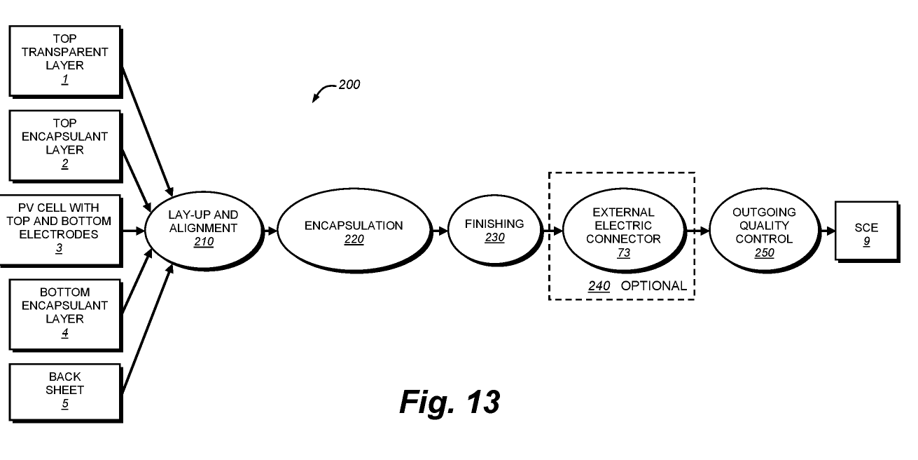

FIG. 13 illustrates a sequence of steps or functions in a process 200 to enable one possible fabrication method which might be implemented to create the SCE. In this illustrative embodiment, the process begins with lay-up and alignment of components (step 210), which have be previously manufactured. In this step, the SCE top electrode (6, described above) is connected to the front electrode of solar cell 3 and SCE bottom electrode (7) is connected to the back electrode of solar cell 3. Solar cell 3 is of the type of PV commercially available from solar cell manufacturers, however the amount of material for the cell bus bars can be substantially reduced when conductive glue, conductive tape or other solder-less interconnection methods are applied. During layup of the SCE, the cell is aligned with SCE top layer 1, top encapsulant layer 2, bottom encapsulant layer 4 and SCE bottom layer (back sheet) 5. The multi-layer structure is then encapsulated (step 220), for example by pressing and heating under vacuum or exposing to ultraviolet radiation or other forms of catalytic agents, for a sufficient amount of time, depending on the materials used and according to practices known to those skilled in the art.

External electric connector 73 can be optionally applied (step 240) and the cell is finished into SCE 9 (step 230). A final outgoing quality control inspection (step 250 can be applied to sort SCE's by measured properties such as: total conversion efficiency, spectrally resolved conversion efficiency, light reflectance, micro-crack analysis (e.g. electroluminescence), mechanical properties, thermal characteristics, lumped electric parameter characteristics (resistance, capacitance and inductance), DC and AC electric characteristics of the junction, current-voltage response (IV curves) at different irradiances and temperatures, and other measurements known to those skilled in the art. By performing outgoing quality control after encapsulation, an accurate estimate is obtained of the real performance of the cell in the field. As a consequence, modules built with SCEs can achieve tight output power distribution at their nominal power rating.

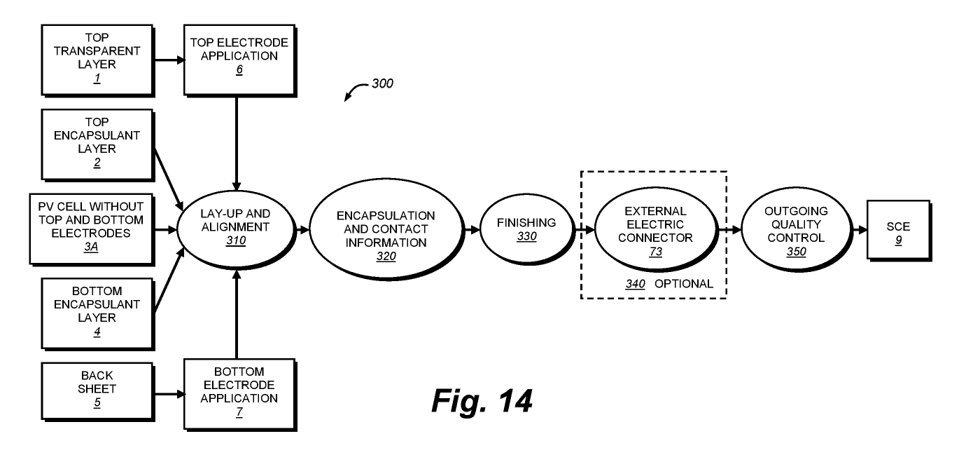

FIG. 14 shows yet another illustrative embodiment of steps in an illustrative manufacturing method. In this embodiment, SCE top electrode 6 and SCE bottom electrode 7 are first applied in the layup step 310 electrically connected to the front and back electrodes of solar cell 3A during encapsulation. In a particular case of such embodiment, solar cell 3A can be free of the front and back electrodes and such electrodes can be created during encapsulation, for example by diffusion of a suitable conductive paste through the front and back of solar cell 3. External electric connector 73 can be optionally applied (step 340), and the cell is finished (step 330) into SCE 9. The cell can then be subjected to an outgoing quality control inspection (step 350) and sorting as previously described.

It should be noted that FIG. 13 and FIG. 14 show only two of a number of potential, illustrative methods for encapsulation that incorporate lamination to manufacture SCE. Other suitable methods of encapsulation include depositing, spraying or painting a layer of suitable materials on one or both sides of solar cell 3, with or without SCE electrodes 6 and 7, with or without SCE top layer 1 and SCE bottom layer 5. Many such materials and methods exist, which produce suitable encapsulation to protect the cell from environmental conditions, as will be known to those skilled in the art. One common characteristic of many such methods is the possibility of adopting a continuous process for single cell encapsulation as opposed to the industry's standard practice of laminating large PV cell assemblies in batches, with significant advantages in terms of process control, reproducibility and yield.

In support of the industry effort to reduce the cost of photovoltaic energy and become competitive with fossil fuel generation, the flexible-format module architecture based on individually encapsulated cells enables significant savings by moving to thinner and cheaper SCE front layer materials; reducing the amount of encapsulant needed; eliminating the external frame of the PV module; and substantially reducing the amount of conductive paste required for the cell front and back bus bars. Furthermore, fast-curing silicone encapsulants are especially suited for single cell encapsulation and enable high-throughput, compact machines with a level of complexity and cost substantially reduced with respect to standard manufacturing equipment. Finally, single cell encapsulation can be implemented in continuous processes, with obvious benefits in terms of process control, reproducibility and yield.

The foregoing has been a detailed description of illustrative embodiments of the invention. Various modifications and additions can be made without departing from the spirit and scope of this invention. Each of the various embodiments described above can be combined with other described embodiments in order to provide multiple features. Furthermore, while the foregoing describes a number of separate embodiments of the apparatus and method of the present invention, what has been described herein is merely illustrative of the application of the principles of the present invention. For example, the sizes, shapes and form factors of components described herein can be varied to suit a particular application. Likewise, additional layers, enclosures, housings and mounting assemblies can be employed in conjunction with SCEs and FMAs as appropriate. Also while orientational terms such “top” and “bottom” are employed, these should be taken as relative only and not in reference to a global coordinate system such as the acting direction of gravity. Moreover, materials used for encapsulant and other components are described by way of non-limiting example, and it is expressly contemplated that other materials that may be developed and/or are known to those of skill in the art having similar performance and properties can be substituted for the above-described materials. Accordingly, this description is meant to be taken only by way of example, and not to otherwise limit the scope of this invention.

What is claimed is:

1. A photovoltaic module comprising:
a substrate with slots for mechanical and electrical connection of stand-alone, multi-layer photovoltaic devices, electric connections among the devices and electronic components constructed and arranged for management and optimization of electric power generation.

2. The photovoltaic module as set forth in claim 1 wherein the substrate defines a supporting frame constructed from weather-resistant materials.

3. The photovoltaic module as set forth in claim 2 wherein the multi-layer photovoltaic devices and the slots are each constructed and arranged to enable direct electrical connection of devices with respect to each other when mounted in the slots adjacently.

4. The photovoltaic module as set forth in claim 2 wherein the slots can include electrical connections that interconnect predetermined of the multi-layer photovoltaic devices together, the electrical connections including bypass diodes constructed and arranged to enable at least one of the devices to be bypassed in an overall electrical connection of the devices based upon predetermined electrical conditions affecting the bypassed one of the devices.

5. The photovoltaic module as set forth in claim 2 wherein the slots can include electrical connections that interconnect predetermined of the multi-layer photovoltaic device together, the electrical connections including power conditioning circuitry associated with at least some of the devices.

6. The photovoltaic module as set forth in claim 5 wherein the power conditioning circuitry includes at least one of a maximum power point tracking stage and a DC-DC voltage step-up power conversion stage.

7. The photovoltaic module as set forth in claim 2 wherein the slots can include electrical connections that interconnect predetermined of the multi-layer photovoltaic device together based upon electrodes that extend from each of the devices, the electrodes being interconnected to at least one central electronic board based upon at least one of a series, parallel and hybrid interconnection configuration.

8. The photovoltaic module as set forth in claim 2 wherein the slots can include electrical connections that interconnect predetermined of the multi-layer photovoltaic device together, the electrical connections being constructed and arranged to interconnect predetermined sub-groups of devices in series and predetermined sub groups in parallel to define a hybrid interconnection of devices and sub-groups.

9. The photovoltaic module as set forth in claim 8 wherein electrical connections include at least one of power conditioning circuits and bypass diodes, each associated with predetermined of the multi-layer photovoltaic device.

10. The photovoltaic module as set forth in claim 2 wherein each of the multi-layer photovoltaic device defines, in order, a bottom layer, an encapsulant bottom layer, a photovoltaic cell, an encapsulant top layer, and a top layer.
